(19) United States
(12) Patent Application Publication
(10) Pub. No.: US 2008/0054317 A1
(43) Pub. Date: Mar. 6, 2008

(54) IMAGE SENSOR AND METHOD FOR MANUFACTURING THE SAME

(76) Inventor: Sang-Chul Kim, Seoul (KR)

Correspondence Address: SHERR & NOURSE, PLLC, 620 HERNDON PARKWAY, SUITE 200, HERNDON, VA, 20170, US

(21) Appl. No.: 11/846,848

(22) Filed: Aug. 29, 2007

(30) Foreign Application Priority Data
Aug. 31, 2006 (KR) 10-2006-0083217

(51) Int. Cl. H01L 27/146; H01L 31/0232; H01L 31/18

(52) U.S. Cl. 257/290; 438/70; 257/E27.133; 257/E31.128

(57) ABSTRACT

An image sensor is provided. The image sensor includes a transistor region over a substrate, an interlayer insulating layer having a via hole over the transistor region, a silicon layer over the interlayer insulating layer, and a photodiode over the silicon layer.

The present application claims priority under 35 U.S.C. 119 to Korean Patent Application No. 10-2006-0083217 (filed on Aug. 31, 2006), which is hereby incorporated by reference in its entirety.

### BACKGROUND

Generally, an image sensor is a semiconductor device which converts an optical image into an electric signal. Image sensors may be classified into charge coupled device (CCD) image sensors and a complementary metal oxide silicon (CMOS) image sensors (CIS). A CIS image sensor may include a photodiode and a metal oxide semiconductor (MOS) transistor in a unit pixel, to sequentially output electric signals from each unit pixel for displaying an image.

A CIS device may be divided into a photodiode region for receiving and converting a light signal into an electric signal, and a transistor region for processing the electric signal. The photodiode may be created in a front-end-of-the-line (FEOL). Due to a metal line formed in a back-end-of-the-line (BEOL) over the transistor, a distance from a microlens to a photodiode through a color filter layer lengthens, such that loss of a light signal incident to the photodiode may increase.

Moreover, since the relatively large photodiode region and the relatively small transistor region may be manufactured simultaneously, it may be difficult to perform a lithography process, and defects frequently occur during manufacturing processes. The characteristics of the CIS may deteriorate because the photodiode may be attacked during the processes of forming the transistor. Furthermore, since a distance from a region onto which light is incident to the photodiode is long, there are many constraints in manufacturing a microlens. Additionally, transistors in the CIS devices may block a portion of the received light, resulting in a degraded signal.

### SUMMARY

Embodiments relate to an image sensor with a photodiode formed on the BEOL, and a method of manufacturing the same. The image sensor may minimize light loss, which may be caused by components formed in a BEOL. Embodiments also provide an image sensor having an excellent light collecting efficiency, and a method of manufacturing the same.

In embodiments, an image sensor includes a transistor region over a substrate. An interlayer insulating layer having a via hole is formed over the transistor region. A silicon layer is formed over the interlayer insulating layer, and a photodiode is formed over the silicon layer. In embodiments, a method of manufacturing an image sensor includes forming an interlayer insulating layer over a substrate having a transistor region. A silicon layer is formed over the interlayer insulating layer. A photodiode is formed over the silicon layer.

### DRAWINGS

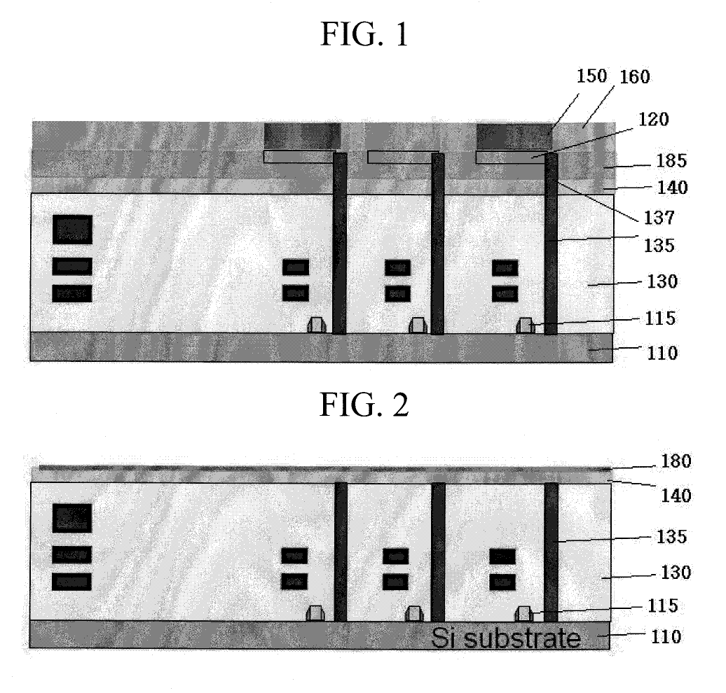

Example FIG. 1 is a sectional view of an image sensor according to embodiments.

Example FIGS. 2 to 6 are sectional views of manufacturing processes of an image sensor according to embodiments.

### DESCRIPTION

Example FIG. 1 is a sectional view of an image sensor according to embodiments. The image sensor may include: a transistor 115 over a substrate 110; an interlayer insulating layer 130, a passivation layer 140, and a silicon layer 185, which may be sequentially formed over the transistor 115 and include a via hole. A photodiode 120 may be formed over the silicon layer 185. Via plugs 135 and 137 may fill the via hole to connect the transistor 115 with the photodiode 120. A color filter layer 150 may be formed over the photodiode 120. A planarization layer 160 may be formed over the entire surface of the substrate 110 having the color filter layer 150.

The image sensor according to embodiments includes a photodiode 120 formed during a back-end-of-the-line (BEOL), not during a front-end-of-the-line (FEOL). That is, the image sensor includes the photodiode 120 over the transistor 115. Moreover, electrons generated in the photodiode 120 may transfer to the transistor 115 through the via plugs 135 and 137 that connect the photodiode 120 with the transistor 115 according to embodiments.

According to embodiments, the photodiode 120 is formed in the BEOL, such that external light may be directly collected on the photodiode 120 without passing through complex paths such as the interlayer insulating layer 130, the passivation layer 140, etc. Consequently, an image sensor may be provided with excellent light collecting efficiency. Furthermore, according to embodiments, the photodiode can be formed independently of a metal layer, such that the degree of integration in a pixel can be improved. Squares in the middle of the interlayer insulating layer 130 of example FIG. 1 represent metal lines.

FIGS. 2 to 6 are sectional views of manufacturing processes of an image sensor according to embodiments. The manufacturing processes of the image sensor according to embodiments are as follows.

First, as illustrated in example FIG. 2, an interlayer insulating layer 130 may be formed over a substrate 110 having a transistor 115. The interlayer insulating layer 130 may be formed in multiple layers, and a metal line may be formed in the interlayer insulating layer 130. The substrate 110 does not have a photodiode in a direction parallel to the transistor 115.

A first via plug 135 is formed in the interlayer insulating layer 130 to connect to the transistor 130. The first via plug 135 may be formed of one of tungsten, aluminum, and copper. A passivation layer 140 is formed over the interlayer insulating layer 130 having the first via plug 135. The passivation layer 140 may be formed of a nitride layer such as SiN. A process of forming the passivation layer 140 may not be necessary.

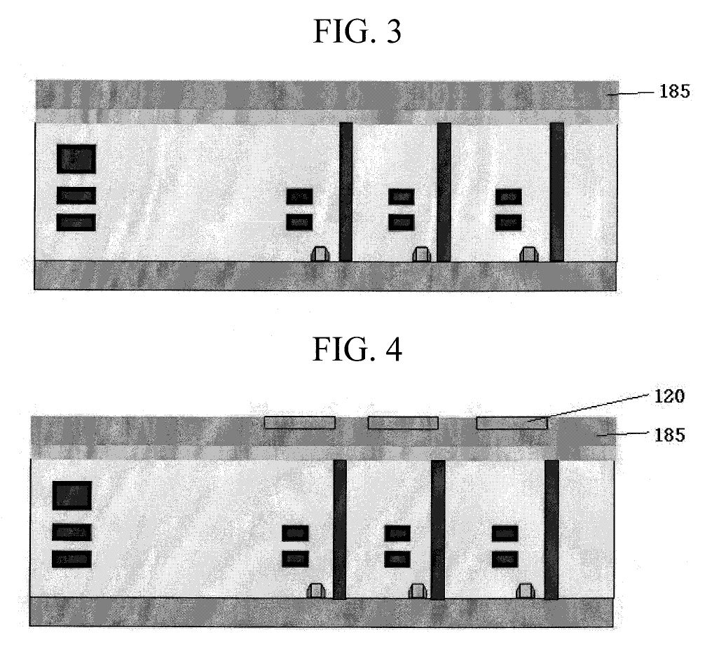

A silicon layer 185 is formed over the passivation layer 140. First, a silicon monolayer may be formed 180 by soaking SiH4 over the passivation layer 140. As illustrated in example FIG. 3, the silicon layer 185 is formed by an epitaxial process using the silicon monolayer 180 as a seed.

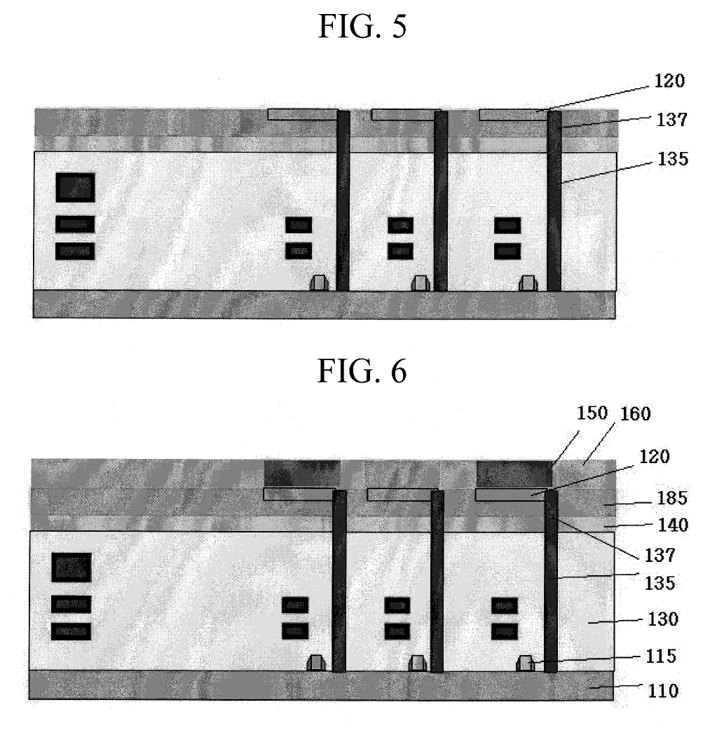

As illustrated in example FIG. 4, a photodiode 120 is formed in the silicon layer 185. For example, the photodiode 120 can be formed using ion implantation. As illustrated in example FIG. 5, a second via plug 137 is formed to connect the photodiode 120 with the first via plug 135. The forming of the second via plug 137 may include etching a portion of the silicon layer 185 and the passivation layer 140 to form a via hole that exposes the first via plug 135. The via hole may be filled to form the second via plug 137 that is connected to the first via plug 135. The second via plug 137 and the first via plug 135 may be formed of the same material.

As illustrated in example FIG. 6, a color filter layer 150 is formed over the photodiode 120 having the second via plug 137. Red, green, and blue color filters are formed by respectively performing a photolithography process on red, green, and blue color resistor layers which constitute the color filter layer 150. After forming the respective red, green, and blue color filters, a UV exposure process may be performed to improve unstable surface states

A planarization layer 160 planarizes the color filter layer 150. A heat treatment hardens the planarization layer 160 at 150 to 300 C°. UV may also be projected over a surface of the planarization layer 160 to stabilize the planarization layer 160.

According to embodiments, light loss may be minimized to maximize performance of the image sensor. According to embodiments, the photodiode may be disposed over the transistor, to allow the image sensor to maximize light collecting efficiency. The photodiode can be formed independently of the metal layer, such that the degree of integration in a pixel can be improved.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a transistor region over a substrate;
an interlayer insulating layer comprising a via hole over the transistor region;
a silicon layer over the interlayer insulating layer; and
a photodiode over the silicon layer.

2. The apparatus of claim 1, comprising a via plug filling the via hole to connect the transistor region with the photodiode.

3. The apparatus of claim 1, comprising a passivation layer between the interlayer insulating layer and the silicon layer.

4. The apparatus of claim 1, comprising a color filter layer over the photodiode.

5. The apparatus of claim 4, comprising a planarization layer over a surface of the substrate comprising the color filter layer.

6. The apparatus of claim 1, wherein the silicon layer is a single crystal silicon layer.

7. The apparatus of claim 6, wherein the single crystal silicon layer is formed using an epitaxial process after forming a silicon monolayer over the interlayer insulating layer.

8. The apparatus of claim 3, wherein the silicon layer is a single crystal silicon layer formed using an epitaxial process after forming a silicon monolayer over the passivation layer.

9. The apparatus of claim 1, wherein the apparatus is a CMOS image sensor.

10. A method comprising:
forming an interlayer insulating layer over a substrate having a transistor region;
forming a silicon layer over the interlayer insulating layer; and
forming a photodiode in the silicon layer.

11. The method of claim 10, comprising forming a first via plug in the interlayer insulating layer to connect to the transistor region.

12. The method of claim 11, comprising forming a passivation layer over the interlayer insulating layer comprising the first via plug.

13. The method of claim 12, further comprising forming a second via plug to connect the photodiode with the first via plug.

14. The method of claim 13, further comprising forming a color filter layer over the photodiode comprising the second via plug.

15. The method of claim 14, further comprising forming a planarization layer over a surface of the substrate comprising the color filter layer.

16. The method of claim 10, wherein the forming of the silicon layer comprises:
forming a silicon monolayer over the interlayer insulating layer; and
forming the silicon layer through an epitaxial process using the silicon monolayer as a seed.

17. The method of claim 16, comprising forming the silicon monolayer by soaking SiH4 over the interlayer insulating layer.

18. The method of claim 13, wherein the forming of the second via plug comprises:
etching a portion of the silicon layer and the passivation layer to form a via hole exposing the first via plug; and
filling the via hole to form the second via plug connected to the first via plug.

19. The method of claim 12, wherein the forming of the silicon layer comprises:
forming a silicon monolayer over the passivation layer; and
forming a silicon layer through an epitaxial process using the silicon monolayer as a seed.

20. The method of claim 19, comprising forming the silicon monolayer by soaking SiH₄ over the passivation layer.
